(19) United States
(12) Patent Application Publication
(10) Pub. No.: US 2021/0356318 A1
(43) Pub. Date: Nov. 18, 2021

(54) VIBRATION SENSOR

(71) Applicant: TAIYO YUDEN CO., LTD., Tokyo (JP)

(72) Inventors: Junji OSHITA, Tokyo (JP); Isao MATSUDA, Tokyo (JP); Takao SHIBUYA, Tokyo (JP); Sakae MOTEGI, Tokyo (JP); Hiroki HORIUCHI, Tokyo (JP)

(73) Assignee: TAIYO YUDEN CO., LTD., Tokyo (JP)

(21) Appl. No.: 17/390,172

(22) Filed: Jul. 30, 2021

Related U.S. Application Data
(63) Continuation of application No. PCT/JP2020/003828, filed on Jan. 31, 2020.

(30) Foreign Application Priority Data
Jan. 31, 2019 (JP) 2019-016427

(51) Int. Cl. G01H 11/08; H01L 41/04; H01L 41/047; H01L 41/053; H01L 41/113; H01L 41/23

(52) U.S. Cl. CPC G01H 11/08; H01L 41/042; H01L 41/0475; G01L 1/16; H01L 41/1132; H01L 41/23; H01L 41/0533

(57) ABSTRACT

A vibration sensor according to an embodiment includes a substrate, a convex member, and a piezoelectric element. The substrate includes a first principal surface and a second principal surface. The substrate transmits vibration. The convex member is fixed on the first principal surface. The piezoelectric element is disposed within a second fixing region on the second principal surface. The second fixing region corresponds to, in a planar view, a first fixing region of the substrate on which the convex member is fixed.

### CROSS-REFERENCE TO RELATED APPLICATIONS

This application is a continuation of PCT International Application No. PCT/JP2020/003828 filed on Jan. 31, 2020, which designates the United States, incorporated herein by reference, and which claims the benefit of priority from Japanese Patent Application No. 2019-016427, filed on Jan. 31, 2019, incorporated herein by reference.

### FIELD

The present disclosure relates to a vibration sensor.

### BACKGROUND

A vibration sensor including a piezoelectric element is brought into contact with an object which can generate vibration. The vibration sensor detects vibration from the object with the piezoelectric element, converts the vibration into an electric signal, and outputs the electric signal (for example, Japanese Patent Application Laid-open No. JP 2017-196211 A).

In such a vibration sensor, when vibration is transmitted from an object to a piezoelectric element, an electric signal is generated as a result of deformation of the piezoelectric element. The vibration sensor performs predetermined amplification processing on the electric signal and outputs the amplified signal. In this event, it is desired to efficiently transmit vibration from the object to the piezoelectric element and prevent EMI noise from being mixed into the signal generated at the piezoelectric element, improving detection accuracy of vibration by the vibration sensor.

### SUMMARY

A vibration sensor according to an embodiment of the present disclosure includes: a substrate including a first principal surface and a second principal surface, the substrate transmitting vibration; a convex member fixed on the first principal surface; and a piezoelectric element disposed within a second fixing region on the second principal surface, the second fixing region corresponding to, in a planar view, a first fixing region of the substrate on which the convex member is fixed.

### BRIEF DESCRIPTION OF THE DRAWINGS

FIG. 1 is a cross-sectional diagram illustrating a configuration of a vibration sensor according to an embodiment;

FIGS. 2A and 2B are each a plan view illustrating the configuration of the vibration sensor according to the embodiment;

FIG. 3 is a cross-sectional diagram illustrating operation of the vibration sensor (in a case where a substrate is fixed in a both-end supported state) according to the embodiment;

FIG. 4 is a cross-sectional diagram illustrating operation of the vibration sensor (in a case where the substrate is fixed in a cantilever state) according to the embodiment;

FIG. 5 is a cross-sectional diagram illustrating operation of a vibration sensor according to a first modified example of the embodiment;

FIGS. 6A and 6B are each a plan view illustrating a configuration of the vibration sensor according to the first modified example of the embodiment;

FIG. 7 is a cross-sectional diagram illustrating a configuration of the vibration sensor according to a second modified example of the embodiment;

FIG. 8 is a cross-sectional diagram illustrating operation of a vibration sensor according to the second modified example of the embodiment;

FIG. 9 is a cross-sectional diagram illustrating a configuration of the vibration sensor according to a third modified example of the embodiment;

FIG. 10 is a cross-sectional diagram illustrating a configuration of the vibration sensor according to a fourth modified example of the embodiment;

FIGS. 11A, 11B, and 11C are each a cross-sectional diagram of process illustrating a manufacturing method of the vibration sensor according to the fourth modified example of the embodiment;

FIG. 12 is a plan view illustrating the manufacturing method of the vibration sensor according to the fourth modified example of the embodiment;

FIG. 13 is a cross-sectional diagram illustrating a configuration of the vibration sensor according to a fifth modified example of the embodiment;

FIGS. 14A and 14B are each a perspective view illustrating a manufacturing method of the vibration sensor according to the fifth modified example of the embodiment; and

FIG. 15 is another plan view illustrating a configuration of the vibration sensor according to the first modified example of the embodiment.

### DETAILED DESCRIPTION

An embodiment of a vibration sensor according to the present invention will be described in detail below on the basis of the drawings. Note that the present invention is not limited to this embodiment.

### Embodiment

A vibration sensor according to an embodiment includes a piezoelectric element. The vibration sensor is brought into contact with an object, and detects vibration from the object with the piezoelectric element. The vibration sensor converts the vibration into an electric signal and outputs the electric signal. The object includes any object which can generate vibration. If vibration from the object is efficiently transmitted to the piezoelectric element of the vibration sensor, sensitivity of a sensor is enhanced, so that it can be expected to improve detection accuracy of vibration in terms of sensitivity. Moreover, if the vibration sensor is able to prevent mixture of EMI noise (electromagnetic noise) caused by an external electromagnetic wave, an S/N ratio with respect to the same sensitivity can be increased, so that it can be expected to improve detection accuracy of vibration in terms of an S/N ratio.

Considering above, in the vibration sensor according to the embodiment, a piezoelectric element is disposed on a principal surface of a substrate that is an opposite side of the object, a conductive film is provided on the principal surface on the object side, and a convex member projecting out from the substrate is provided. With this structure, efficient transmission of vibration to the piezoelectric element and efficient reduction of electromagnetic noise can be achieved.

Specifically, the vibration sensor is structurally improved to flexibly warp the substrate. On the substrate, components are mounted on one of surfaces (a principal surface on an opposite side of the object), and a convex structure (convex member) is provided on a back surface (a principal surface on which the object is mounted) to warp the substrate from the back surface side. The substrate is caused to flexibly warp via the convex member when vibration is transmitted from the object to the substrate side. This enables force by vibration to be efficiently applied to the piezoelectric element and enables the piezoelectric element to efficiently detect the force and a frequency. The whole of the back surface side is covered with a conductive film, and the conductive film is electrically connected to a ground potential. This enables the piezoelectric element and a path of an output signal from the piezoelectric element to be shielded from electromagnetic noise.

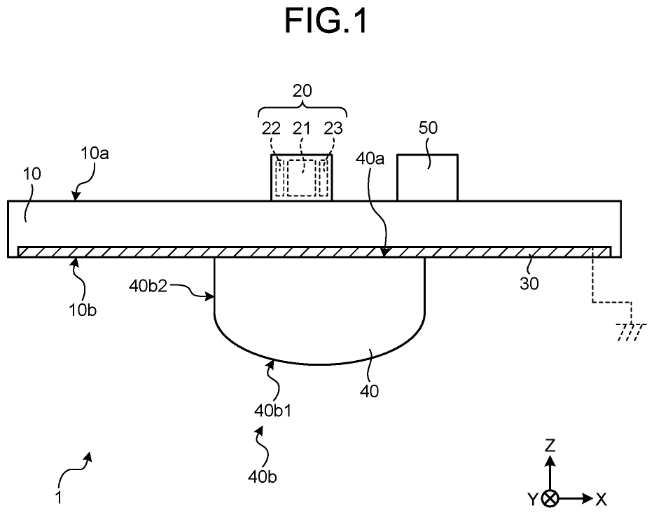

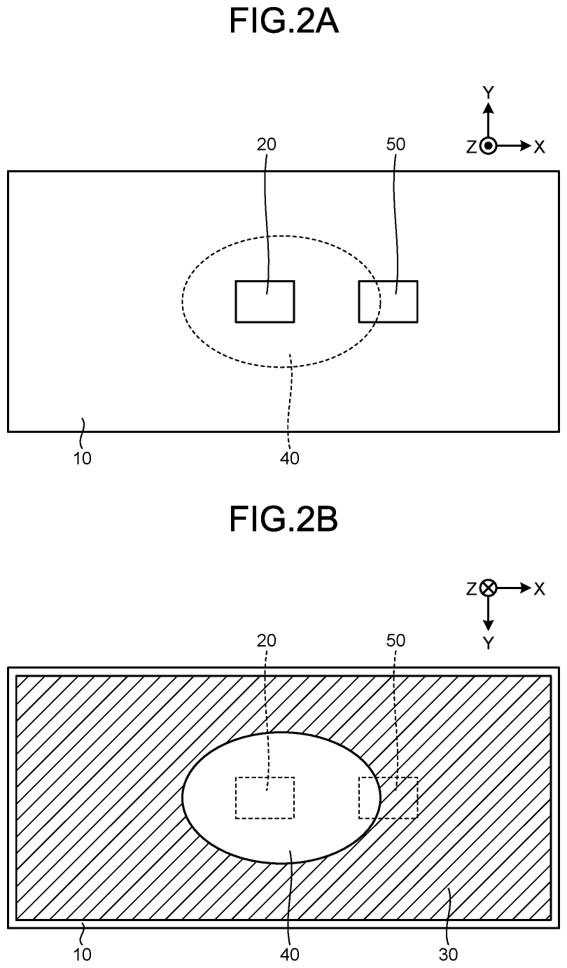

More specifically, a vibration sensor 1 can be constituted as illustrated in FIG. 1 and FIGS. 2A-2B. FIG. 1 is a cross-sectional diagram illustrating configuration of the vibration sensor 1. FIGS. 2A-2B are each a plan view illustrating the configuration of the vibration sensor 1. In FIG. 1 and FIGS. 2A-2B, a direction perpendicular to a surface of the substrate is depicted as a Z direction, and two directions orthogonal to each other in a plane perpendicular to the Z direction are depicted as an X direction and a Y direction. FIG. 2A is a plan view where the substrate is viewed from a +Z side. FIG. 2B is a plan view where the substrate is viewed from a −Z side.

The vibration sensor 1 includes a substrate 10, a piezoelectric element 20, a conductive film 30, a convex member 40, and an element 50.

The substrate 10 has a substantially plate shape extending in an XY direction. The substrate 10 includes a front surface (second principal surface) 10a and a back surface (first principal surface) 10b. The substrate 10 may have a rectangular or substantially rectangular shape or may have a substantially square shape in an XY planar view. The substrate 10 may have a size of, for example, 15 mm×15 mm×0.8 mm. In the example illustrated in FIG. 2A, the substrate 10 has a substantially rectangular shape having a longitudinal direction in the X direction. The front surface 10a and the back surface 10b are principal surfaces facing in the opposite directions to each other. The back surface 10b extends in the XY direction. The back surface 10b is a surface on a side of receiving vibration and can be a principal surface on a side of an object (for example, part of a human body) with which the vibration sensor 1 is brought into contact during use of the vibration sensor 1. The front surface 10a extends in the XY direction. The front surface 10a becomes a principal surface on an opposite side of the object. The substrate 10 may be formed with an insulating material and can be formed with a material which contains an insulating resin (for example, glass epoxy) or insulating ceramic (for example, alumina) as principal components. Note that the substrate 10 may be a metal plate or an alloy plate, each of whose front surface 10a has been subjected to insulating treatment. In FIGS. 2A and 2B, the substrate 10 has a rectangular planar shape with a length which allows grasping of both a right side and a left side. In this manner, the substrate 10 may have any structure, so long as that the substrate 10 can be grasped, and may have a structure obtained by cutting both sides of a circular shape, an elliptical shape, a diamond shape, or the like, to provide linear sides having a certain length to allow grasping.

The piezoelectric element 20 is disposed on the front surface 10a of the substrate 10. As illustrated in FIG. 2A, the piezoelectric element 20 can be disposed near the center of the substrate 10 in an XY planar view. The piezoelectric element 20 can be fixed and supported on the front surface 10a of the substrate 10. The piezoelectric element 20 may have the size of 3.2 mm×1.6 mm×0.8 mm, for example. The piezoelectric element 20 is positioned within a fixing region of a convex member 40, which is a region where the front surface 10a of the substrate 10 overlaps with the convex member 40 in a perspective view from the Z direction.

The piezoelectric element 20 illustrated in FIG. 1 includes, for example, a piezoelectric body 21, a terminal electrode 22, and a terminal electrode 23. The piezoelectric body 21 may have a single plate structure. The piezoelectric body 21 may be formed with a piezoelectric material and can be formed with a material which contains, for example, lead zirconate titanate (PZT) as a principal component. The piezoelectric body 21 may be polarized by polarized terminals being respectively provided on a +Z side and a −Z side in advance and a predetermined voltage being applied from the XY direction, and the polarization direction can be set as the Z direction. The terminal electrode 22 and the terminal electrode 23 of the piezoelectric element 20 are disposed on sides opposite to each other across the piezoelectric body 21. The terminal electrode 22 can be disposed on a −X side of the piezoelectric body 21, and the terminal electrode 23 can be disposed on a +X side of the piezoelectric body 21. According to this configuration, in a case where the piezoelectric body 21 is deformed by receiving force in the X direction and/or the Y direction, polarization (surface charge) emerges at the terminal electrode 22 and the terminal electrode 23 by a piezoelectric effect, which generates a voltage between the terminal electrode 22 and the terminal electrode 23, and a signal in accordance with the force can be output from the piezoelectric element 20.

Here, vibration modes of the piezoelectric element include a d33 mode, which is a mode of vibration in a polarization direction, and a d31 mode or a d32 mode, which is a mode of vibration in a direction orthogonal to the polarization direction. For example, in a case where the Z direction is set as the polarization direction, the d33 mode is a vibration mode in the Z direction, and the d31 mode is a vibration mode in the X direction, and the d32 mode is a vibration mode in the Y direction. In a case where the piezoelectric element 20 is mounted on the substrate 10 as in the present embodiment, when the substrate 10 is warped, stress by vibration in the d31 direction (X direction) of the piezoelectric element 20 becomes greater than stress by vibration in the d33 direction (Z direction) of the piezoelectric element 20. Thus, by mounting the piezoelectric element 20 on the substrate 10 such that the d31 mode becomes a vibration mode in the X direction and the piezoelectric element 20 is deformed with the d31 mode in the X direction, the piezoelectric element 20 has higher excitation efficiency and can achieve a higher sensitive sensor in comparison with the d33 mode in the Z direction. Note that, while the piezoelectric element 20 is preferably mounted on the substrate 10 such that the d31 mode becomes a vibration mode in the X direction, the sensing is possible even if the piezoelectric element 20 is mounted on the substrate 10 such that the d32 mode becomes a vibration mode in the X direction. Alternatively, the sensing is also possible even if the piezoelectric element 20 is mounted on the substrate 10 such that the d33 mode becomes a vibration mode in the X direction.

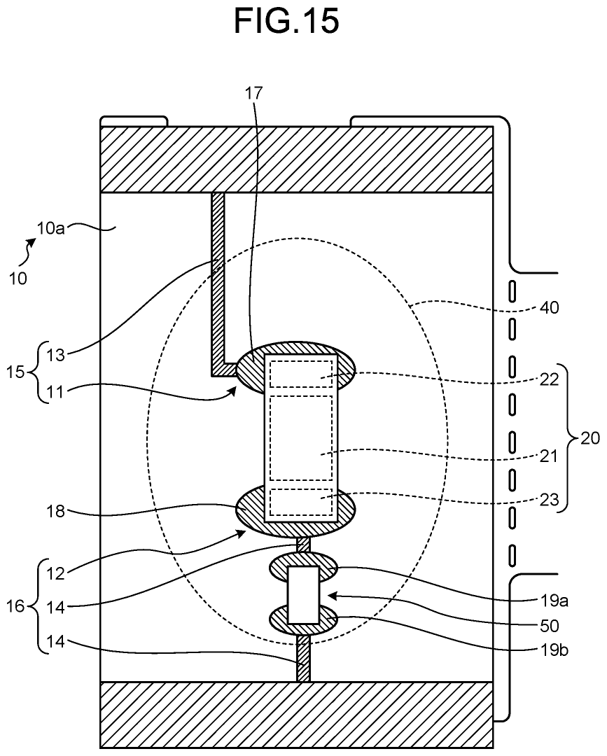

As illustrated in FIG. 15, on the front surface 10a of the substrate 10, a conductive patterns 15, 16 in which electrodes 11, 12 and wirings 13, 14 integral with the electrodes 11, 12 are formed, and the terminal electrode 22 and the terminal electrode 23 may be respectively bonded to the electrodes 11, 12 on the front surface 10a of the substrate 10 with conductive bonding materials 17, 18 such as solder. In other words, the piezoelectric element 20 is electrically connected to the conductive patterns 15, 16. Note that the conductive patterns 15, 16 and the piezoelectric element 20 may be respectively covered with insulating resin. The wiring 14 is electrically connected to an element 50 and achieves a desired circuit configuration. One end of the element 50 may be electrically connected to the piezoelectric element 20 via a conductive bonding material 19a and the wiring 14 and the other end of the element 50 may be electrically connected to another conductive pattern via to a conductive bonding material 19b and the wiring 14.

The element 50 is disposed on the front surface 10a of the substrate 10. The element 50, which is a peripheral component of the piezoelectric element 20, may be, for example, a semiconductor element such as a field effect transistor (FET) which performs amplification processing on a signal generated at the piezoelectric element 20 or may be, for example, a resistive element such as a chip resistor which performs predetermined processing on a signal generated at the piezoelectric element 20. Although FIG. 15 exemplifies a single element 50 arranged on the front surface 10a of the substrate 10, multiple elements 50 may be arranged on the front surface 10a of the substrate 10. As illustrated in FIG. 2A, the element 50 can be disposed near the piezoelectric element 20 in an XY planar view. The element 50 can be fixed and supported on the front surface 10a of the substrate 10. For example, the element 50 may include a plurality of terminal electrodes, and the plurality of terminal electrodes may be respectively bonded to electrodes on the front surface 10a of the substrate 10 with a conductive bonding material such as solder. Here, on the front surface 10a of the substrate 10, a region where the front surface 10a overlaps with the convex member 40 in a perspective view from the Z direction is called, for convenience sake, a fixing region of the convex member 40. The element 50 may be provided within the fixing region of the convex member 40 or may be provided outside this fixing region.

A conductive film 30 is disposed on the back surface 10b of the substrate 10. The conductive film 30 may extend in the XY direction between sides of the substrate 10 from the substrate 10 and the circumference of the convex member 40, and may extend to an outer side of the convex member 40 in an XY planar view as illustrated in FIG. 2B. The conductive film 30 may be continuously provided or may be discontinuously provided, in a mesh shape, on the back surface 10b of the substrate 10. Moreover, the conductive film 30 may cover a region that includes the piezoelectric element 20 and has a large area on the outer side of the piezoelectric element 20 on the back surface 10b in a perspective view from the Z direction. The conductive film 30 may cover a region that includes the piezoelectric element 20 and the element 50 and has large areas respectively on the outer sides of the piezoelectric element 20 and the element 50 on the back surface 10b in a perspective view from the Z direction. As illustrated in FIG. 1 and FIG. 2B, the conductive film 30 may cover the whole of the back surface 10b of the substrate 10. Note that, in FIG. 2B, the conductive film 30 covers the whole area except slight space (where a lead line of reference numeral 10 is drawn) on inner sides from respective sides of the substrate 10.

The conductive film 30 may be formed with a material which contains a metal (for example, copper or aluminum) as a principal component. As indicated with a broken line in FIG. 1, the conductive film 30 can be electrically connected to a ground potential. This enables, for example, electromagnetic noise to be converted into a noise current, such as an induced current, at the conductive film 30 in a case where the electromagnetic noise comes from the −Z side, and allows the converted noise current to escape to the ground potential from the conductive film 30. Thus, it is possible to shield the piezoelectric element 20, other elements 50 and signal paths thereof from the electromagnetic noise.

The convex member 40 is disposed on the back surface 10b of the substrate 10. As illustrated in FIG. 2B, the convex member 40 can be disposed at a position corresponding to the piezoelectric element 20 on the back surface 10b of the substrate 10.

Here, the arrangement that the convex member 40 is disposed at a position corresponding to the piezoelectric element 20 on the back surface 10b of the substrate 10 means that there is an overlapping portion between a region where the piezoelectric element 20 is disposed on the substrate 10 and a region where the convex member 40 is disposed on the substrate 10 in a perspective view from the Z direction. In a perspective view from the Z direction, the convex member 40 may be disposed at a position including the piezoelectric element 20 or may be disposed at a position where the center of the convex member 40 overlaps with the piezoelectric element 20 on the back surface 10b.

Widths in a plane of the convex member 40 (that is, lengths of the long axis and the short axis in an elliptical shape of the convex member 40) are considerably smaller than widths in a plane of the substrate 10. The convex member 40 may have a size of, for example, 9.5 mm radius and 4.0 mm height. As illustrated in FIG. 2B, the width in a planar view in the X direction of the convex member 40 is considerably smaller than the width in a planar view in the X direction of the substrate 10. The width in a planar view in the Y direction of the convex member 40 is considerably smaller than the width in a planar view in the Y direction of the substrate 10. The widths in a plane of the convex member 40 may be smaller than widths in a plane of the conductive film 30. The width in a planar view in the X direction of the convex member 40 may be smaller than the width in a planar view in the X direction of the conductive film 30. The width in a planar view in the Y direction of the convex member 40 may be smaller than the width in a planar view in the Y direction of the conductive film 30.

The convex member 40 can be fixed on the back surface 10b of the substrate 10. The convex member 40 bulges out in a −Z direction from the back surface 10b of the substrate 10. The convex member 40 may be fixed at substantially the center of the substrate 10 on the back surface 10b of the substrate 10. The convex member 40 may be brought into contact with the conductive film 30 and projects downward from a back side of the substrate with respect to the conductive film 30 (see FIG. 1). The convex member 40 can be formed with any material which can transmit stress caused by vibration to the substrate 10. In a case where the convex member 40 is formed with a metal, the convex member 40 may be fixed on the back surface 10b of the substrate 10 by the convex member 40 being alloy-jointed to the conductive film 30. In a case where the convex member 40 is formed with a material other than a metal, the convex member 40 may be fixed on the back surface 10b of the substrate 10 by the convex member 40 being bonded to the conductive film 30 with an adhesive agent, or the like. In a case where the convex member 40 is formed with a metal, the convex member 40 may be fixed on the back surface 10b of the substrate 10 by the convex member 40 being fixed to the conductive film 30 with an adhesive agent. The adhesive agent may be a fixing agent having conductivity and adhesiveness, and is, for example, a brazing material, conductive paste, a conductive resin, or the like. Note that a material of the adhesive agent to be employed in the present embodiment may be an acrylic instant adhesive. A modulus of elasticity is, for example, 8 MPa.

The convex member 40 includes at least a flat surface 40a and a convex surface 40b. The flat surface 40a flatly extends in the XY direction. The flat surface 40a of the convex member 40 is a fixing surface to be fixed on the back surface 10b of the substrate 10. The convex surface 40b protrudes in a −Z direction from an end portion of the flat surface 40a (which abuts on the substrate 10). The convex surface 40b vertically extends in a −Z direction from the end portion of the flat surface 40a and forms a closed surface with the flat surface 40a from halfway. The convex surface 40b can be a curved surface which becomes a convex in the −Z direction. The convex surface 40b may include a cylindrical surface 40b2 and a bulging surface 40b1. The cylindrical surface 40b2, which is a surface extending in a substantially cylindrical shape in the Z direction while keeping a substantially constant dimension in the X direction, may have a substantially circular shape or a substantially elliptical shape in an XY planar view. The flat surface 40a of the convex member 40 may be fixed at substantially the center of the substrate 10 on the back surface 10b with an adhesive agent.

In other words, a portion indicated by the reference numeral 40b2 of the convex member 40 is a cylindrical member which has a circular or elliptical cross-section when the cylindrical member is cut in a horizontal direction. A portion indicated by the reference numeral 40b1 is a member which bulges in a lenticular shape from the cylindrical member and has a shape like a cross-section obtained by cutting a circular ball or an elliptical ball.

In FIG. 2B, the cylindrical surface 40b2 is exemplified such that it has a substantially elliptical shape in an XY planar view. The bulging surface 40b1 curves and bulges in a convex shape from the end portion on the −Z side of the cylindrical surface 40b2 and bulges in an arc shape from the end portion on the −Z side of the cylindrical surface 40b2 to the −Z side in XZ cross-sectional view. The bulging surface 40b1 may be a substantially spherical surface or may be an aspheric surface. Note that the convex member 40 may be constituted with the bulging surface 40b1 without the cylindrical surface 40b2.

The convex member 40, which is a member for receiving vibration, is brought into contact with an object (for example, part of a human body) during use of the vibration sensor 1.

For the sake of transmitting, to the substrate 10, force caused by vibration received at the convex member 40, the substrate 10 may be fixed in a cantilever state or in a both-end supported state by using another member which can fix the substrate 10. For example, the arrangement that the vibration sensor 1 is mounted on an appropriate position such as the arm, the wrist, or the neck of the human body with a medical fixing tape such that the convex member 40 is in contact with the skin of the human body corresponds to a case where the substrate 10 is fixed in a both-end supported state with another member which can fix the substrate 10.

In other words, referring to FIGS. 2A and 2B, a state where one of short sides of a rectangle facing each other is supported from one end across the other end is a cantilever state, and a state where two short sides facing each other are supported from one ends across the other ends is a both-end supported state.

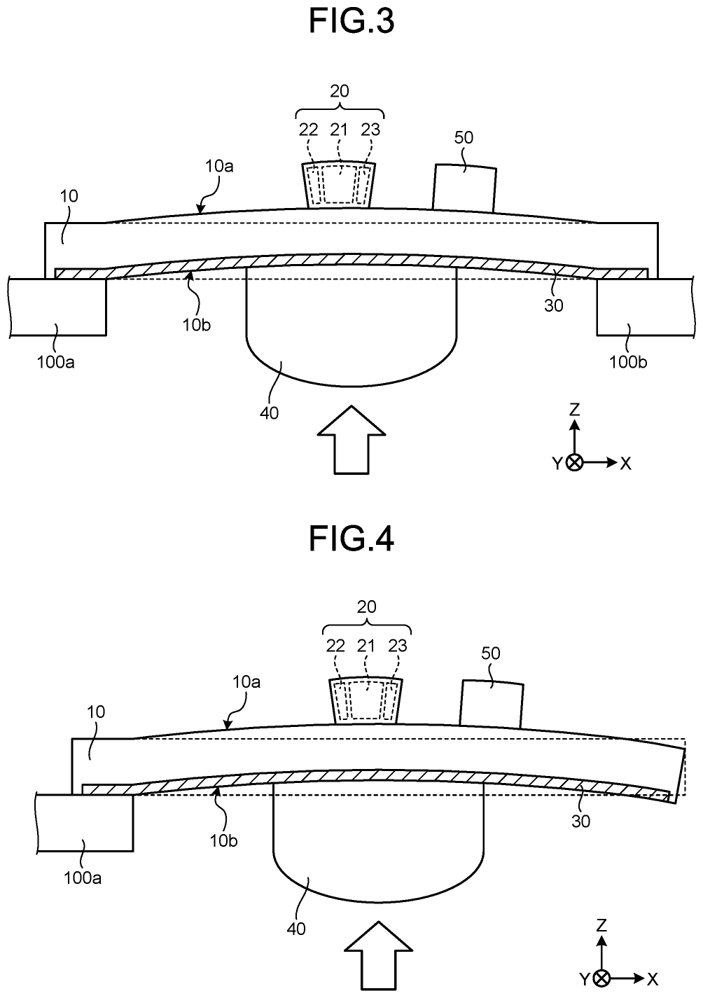

As illustrated in FIG. 3, the substrate 10 is fixed in, for example, a both-end supported state with other members 100a and 100b. In a case where the substrate 10 has a substantially rectangular shape in an XY planar view, two short sides of the substrate 10 may be supported. In this case, as indicated with a white arrow, when the convex member 40 receives force caused by vibration from an object (for example, part of a human body), the force is transmitted to the substrate 10 from the convex member 40, and the substrate 10 is displaced from a position indicated with a dashed line to a position indicated with a solid line, which becomes vertical warp. FIG. 3 is a cross-sectional diagram illustrating operation of the vibration sensor 1 (in a case where a substrate is fixed in a both-end supported state). In this case, the widths in a plane of the convex member 40 are smaller than the widths in a plane of the substrate 10, so that the convex member 40 can efficiently warp the substrate 10. In addition, the convex member 40 is disposed at a position corresponding to the piezoelectric element 20 on the back surface 10b of the substrate 10, so that it is possible to efficiently warp a region near the piezoelectric element 20 on the front surface 10a of the substrate 10. This enables the piezoelectric body 21 of the piezoelectric element 20 to be efficiently deformed and enables the piezoelectric element 20 to detect force by vibration with high sensitivity.

Moreover, as illustrated in FIG. 4, the substrate 10 is fixed in, for example, a cantilever state with the other member 100a. In this case, when the substrate 10 has a substantially rectangular shape in an XY planar view, one short side of the substrate 10 may be supported. As indicated with an white arrow, in a case where the convex member 40 receives force caused by vibration from an object (for example, part of a human body), the force is transmitted to the substrate 10 from the convex member 40, and the substrate 10 is displaced from a position indicated with a dashed line to a position indicated with a solid line, which becomes warp. FIG. 4 is a cross-sectional diagram illustrating operation of the vibration sensor 1 (in a case where a substrate is fixed in a cantilever state). In this case, the widths in a plane of the convex member 40 are considerably smaller than the widths in a plane of the substrate 10, so that the convex member 40 can efficiently warp the substrate 10. In addition, the convex member 40 is disposed at a position corresponding to the piezoelectric element 20 on the back surface 10b of the substrate 10, so that it is possible to efficiently warp a region near the piezoelectric element 20 on the front surface 10a of the substrate 10. This enables the piezoelectric body 21 of the piezoelectric element 20 to be efficiently deformed and enables the piezoelectric element 20 to detect force by vibration with high sensitivity.

As described above, in the embodiment, the piezoelectric element 20 is disposed on the front surface 10a on an opposite side of the object on the substrate 10, and the conductive film 30 and the convex member 40, which projects out from the conductive film 30, are provided on the back surface 10b on the object side at the vibration sensor 1. This enables efficient transmission of (force caused by) vibration to the piezoelectric element 20 and can efficiently reduce electromagnetic noise.

In particular, in FIG. 2A, when right and left sides of the rectangle are supported in a both-end supported state, the center of the rectangle and its vicinity in the substrate 10 are most deformed. Thus, the center in a planar view of the convex member 40, which first receives vibration, preferably overlaps with the center of the rectangle and its vicinity.

Moreover, the flat surface 40a of the convex member is fixed with the substrate 10 with an adhesive agent. Thus, even when the convex member 40 is a soft material like an acrylic resin, flatness of the fixing region tends to be maintained because the fixing region does not largely curve although the fixing region curves to some extent. A modulus of elasticity of this acrylic resin is, for example, 10 MPa.

Furthermore, flatness of a flat surface corresponding to the fixing region and a surface of the substrate tends to be held as in FIG. 4 because of hardness of the convex member and/or hardness after the adhesive agent is hardened.

The fixing region may bring improvement of reliability of the piezoelectric element 20 and the element 50.

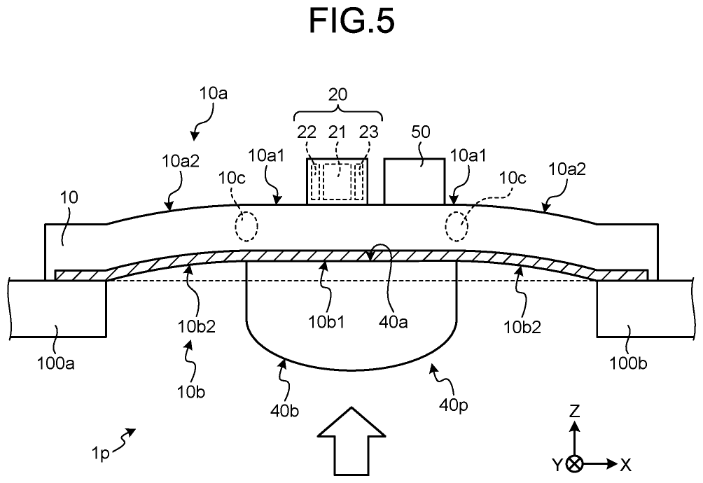

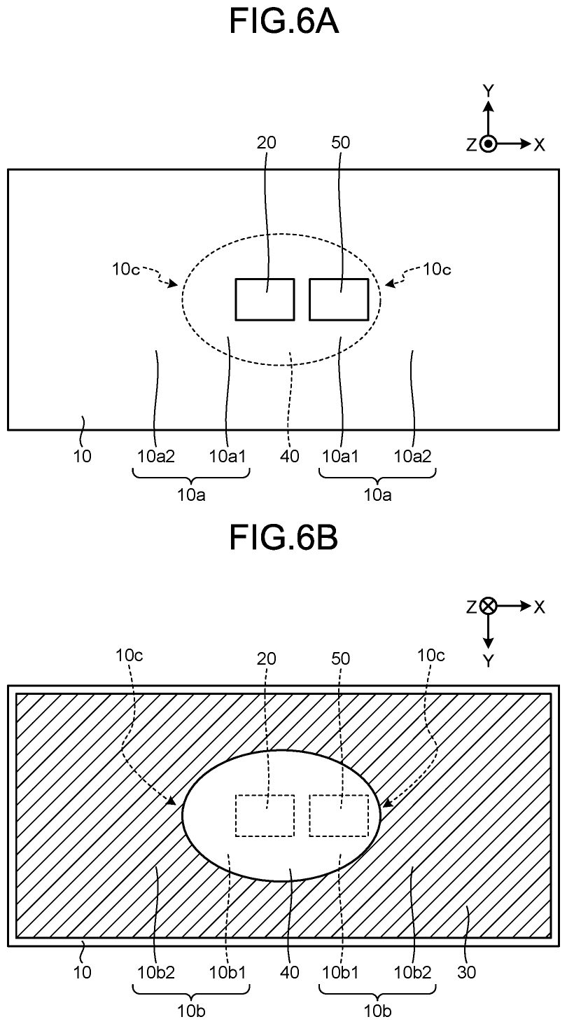

As illustrated in FIG. 5, a convex member 40p and/or the adhesive agent to be applied to the substrate 10 at a vibration sensor 1p may be formed with a material which can maintain flatness of the flat surface 40a when large stress is received from a side of the bulging surface 40b1. The material of the convex member 40p which can maintain flatness of the flat surface 40a may be, for example, a metal, a resin or rubber which has rigidity and which can maintain flatness. The adhesive agent which can maintain flatness of the flat surface 40a may be a curable high-impact resin, or the like. FIG. 5 is a cross-sectional diagram illustrating operation of a vibration sensor 1p according to the first modified example of the embodiment. In a perspective view from the Z direction as illustrated in FIG. 6A, a region of the front surface 10a of the substrate 10, which overlaps with the convex member 40p, will be referred to as a convex portion corresponding area (fixing region) 10al, and a region around the convex portion corresponding area will be referred to as a convex portion non-corresponding area (non-fixing region) 10a2. In a perspective view from the Z direction as illustrated in FIG. 6B, a region of the back surface 10b of the substrate 10, which overlaps with the convex member 40p, will be referred to as a convex portion corresponding area (fixing region) 10b1, and a region around the convex portion corresponding area will be referred to as a convex portion non-corresponding area (non-fixing region) 10b2. The convex portion corresponding area 10b1 is a fixing region where the flat surface 40a of the convex member 40p is fixed. The convex portion non-corresponding area 10b2 is a non-fixing region where the flat surface 40a of the convex member 40p is not fixed.

For example, as illustrated in FIG. 5, in a case where the substrate 10 is fixed in a both-end supported state with other members 100a and 100b, when the convex member 40p receives force by vibration from an object (for example, part of a human body) as indicated with a white arrow, the force is transmitted to the substrate 10 from the convex member 40p, and the substrate 10 is displaced from a position indicated with a dashed line to a position indicated with a solid line and can be warped. With this displacement, other members 100a and 100b pull the substrate 10 from the both end portion and thereby stress components oblique to the XY direction occur in the convex portion non-corresponding area 10a2 of the substrate 10. The force in the Z direction and the stress components oblique to the XY direction may be synthesized into stress components in the XY direction in the convex portion corresponding area 10a1 of the substrate 10. The flat surface 40a of the convex member 40p is formed with a material which can maintain flatness, and thus, the convex member 40 can prevent the convex portion corresponding areas 10a1 and 10b1 from being curved, can cause the convex portion non-corresponding areas 10a2 and 10b2 to be curved with high curvature while maintaining the flatness of the convex portion corresponding areas 10a1 and 10b1, and can efficiently warp the substrate 10. In other words, as illustrated in FIG. 5, in a case where stress is applied to the convex member 40p from a side of the convex surface 40b (−Z side), flatness of the convex portion corresponding areas (fixing region) 10a2 and 10b2 of the substrate 10 is maintained by appropriate hardness due to solidification of the adhesive agent or appropriate hardness of a portion of the flat surface 40a of the convex member 40p, which makes a degree of curvature different between the convex portion corresponding areas (fixing region) 10a1 and 10b1 and the convex portion non-corresponding areas (non-fixing region) 10a2 and 10b2. Specifically, the convex portion non-corresponding areas 10a2 and 10b2 are curved more than the convex portion corresponding areas 10a1 and 10b1 of the substrate 10. In the convex portion corresponding area 10al, warp in the XY direction (or stress components in the XY direction) is transmitted to a region near the piezoelectric element 20 while warp in the Z direction is suppressed, and the warp in the Z direction is efficiently absorbed in the convex portion non-corresponding area 10a2 using a boundary portion 10c between the convex portion corresponding area 10a1 and the convex portion non-corresponding area 10a2 as a fulcrum. By this means, the flatness of the convex portion corresponding area 10a1 can be maintained, so that it is possible to prevent crack of a conductive bonding material such as solder and improve reliability of the piezoelectric element 20. In addition, the piezoelectric body 21 can be efficiently deformed by warp in the XY direction (or stress components in the XY direction) in the convex portion corresponding area 10a1 because the polarity of the piezoelectric element 20 is the XY direction, so that it is possible to cause the piezoelectric element 20 to detect force by vibration with high sensitivity. In other words, it is possible to achieve both improvement in reliability and improvement in sensitivity of the piezoelectric element 20. It should be noted that “appropriate hardness” means a hardness appropriate for the flatness of the convex portion corresponding area 10a1 and also means a hardness appropriate for the transmission of stress components in the XY direction.

Moreover, as illustrated in FIG. 6A, the element 50 other than the piezoelectric element 20 may be disposed on the front surface 10a of the substrate 10 to avoid the boundary portion 10c between the convex portion corresponding area 10a1 and the convex portion non-corresponding area 10a2. The element 50 may be disposed within the convex portion corresponding area 10a1 or may be disposed within the convex portion non-corresponding area 10a2 in a perspective view from the Z direction. In FIG. 6A, the element 50 is disposed within the convex portion corresponding area 10a1. This can improve flatness of a region where the element 50 is disposed compared to a case where the element 50 is disposed across the boundary portion 10c on the front surface 10a of the substrate 10 and can suppress stress to the element 50, so that it is possible to prevent crack of the conductive bonding material such as solder and improve reliability of the element 50.

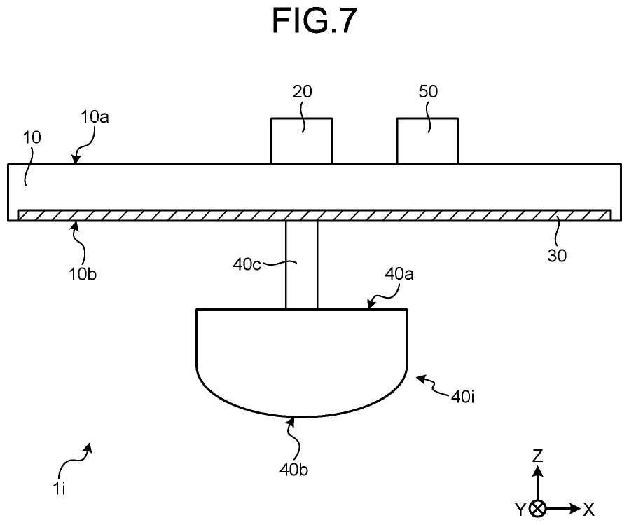

Alternatively, as illustrated in FIG. 7, a convex member 40i of a vibration sensor 1i may be constituted to be in substantially point-contact with the back surface 10b of the substrate 10. FIG. 7 is a cross-sectional diagram illustrating a configuration of the vibration sensor 1i according to the second modified example of the embodiment. The vibration sensor 1i includes a convex member 40i in place of the convex member 40 (see FIG. 1). The convex member 40i further includes a rod-like member 40c. The rod-like member 40c is disposed at a position corresponding to the piezoelectric element 20 on the back surface 10b side of the substrate 10 and is disposed between the back surface 10b of the substrate 10 and the flat surface 40a of the convex member 40i. An end portion on the −Z side of the rod-like member 40c is in contact with the flat surface 40a and can be fixed on the flat surface 40a. An end portion on the +Z side of the rod-like member 40c is in contact with the back surface 10b of the substrate 10 and can be fixed on the back surface 10b of the substrate 10. The end portion on the +Z side of the rod-like member 40c is in contact with the conductive film 30 and can be fixed on the conductive film 30. An area of the end portion on the +Z side of the rod-like member 40c, which is in contacting with the back surface 10b, is smaller than an area of the flat surface 40a. This configuration can be regarded as a configuration where the rod-like member 40c is in substantially point-contact with the back surface 10b of the substrate 10.

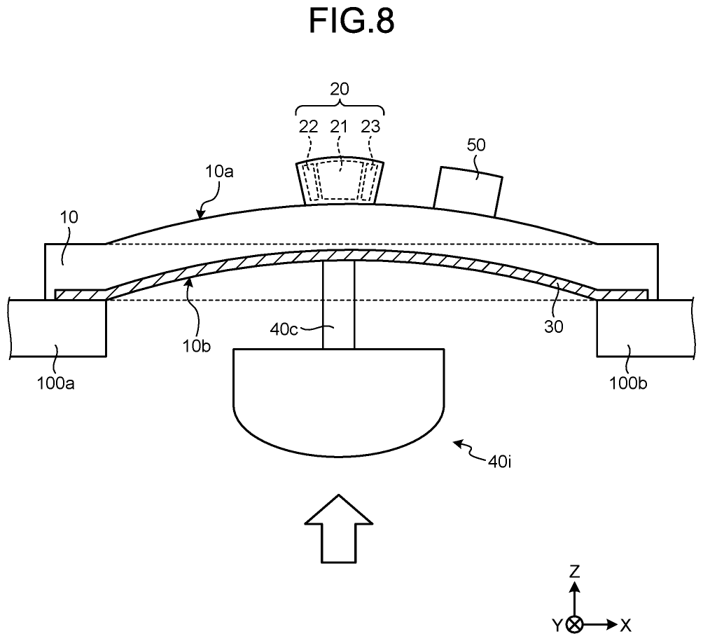

As illustrated in FIG. 8, in a case where the substrate 10 is fixed in a both-end supported state with other members 100a and 100b, when the convex member 40i receives force caused by vibration from an object (for example, part of a human body) as indicated with a white arrow, the force is transmitted to the substrate 10 from the rod-like member 40c of the convex member 40i, and the substrate 10 is displaced from a position indicated with a dashed line to a position indicated with a solid line and can be warped. FIG. 8 is a cross-sectional diagram illustrating operation of the vibration sensor 1i. In this case, the rod-like member 40c of the convex member 40i is in substantially point-contact with the back surface 10b of the substrate 10, so that the convex member 40i can warp the substrate 10 further efficiently. This enables the piezoelectric body 21 of the piezoelectric element 20 to be further efficiently deformed and enables the piezoelectric element 20 to detect force by vibration with further high sensitivity.

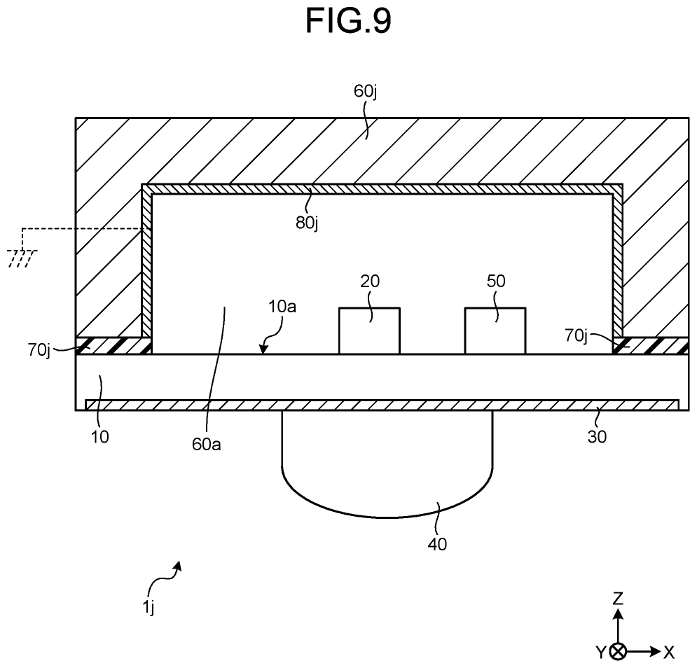

As illustrated in FIG. 9, a vibration sensor 1j may include a waterproof structure around the piezoelectric element 20 because it is not necessary to provide a member for transmitting vibration from an object around the piezoelectric element 20. FIG. 9 is a cross-sectional diagram illustrating a configuration of the vibration sensor 1j according to the third modified example of the embodiment. The vibration sensor 1j includes, for example, a cover 60j, an adhesive layer 70j, and a conductive film 80j. The cover 60j is disposed on the front surface 10a side of the substrate 10 and encloses the piezoelectric element 20 on the front surface 10a side. The cover 60j can be formed with any material such as an insulating resin, which can block external moisture. The cover 60j has an opening structure 60a which is open toward the piezoelectric element 20 side. The adhesive layer 70j seals an end portion of the opening structure 60a of the cover 60j to a circumferential portion on the front surface 10a of the substrate 10. This can substantially block space enclosed with the cover 60j and the substrate 10 from external space and can protect the piezoelectric element 20 and other elements 50 from external moisture.

Moreover, the conductive film 80j covers a surface of the cover 60j on the piezoelectric element 20 side (that is, an inner surface of the cover 60j). The conductive film 80j may be formed with a material which contains a metal (for example, copper or aluminum) as a principal component. As indicated with a broken line in FIG. 9, the conductive film 80j can be electrically connected to a ground potential. This enables, for example, electromagnetic noise to be converted into a noise current such as an induced current at the conductive film 80j in a case where the electromagnetic noise comes from the +Z side, and allows the converted noise current to escape to the ground potential from the conductive film 80j. Thus, it is possible to shield further definitely the piezoelectric element 20, other elements 50 and signal paths thereof from the electromagnetic noise.

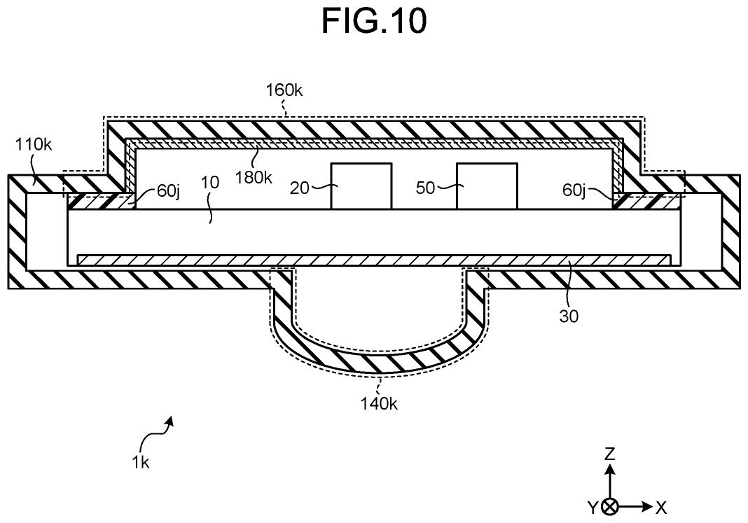

As illustrated in FIG. 10, the convex member and the cover may be respectively integrally molded as part of a common case at a vibration sensor 1k. FIG. 10 is a cross-sectional diagram illustrating a configuration of the vibration sensor 1k according to a fourth modified example of the embodiment. The vibration sensor 1k includes, for example, a case 110k containing a convex member 140k, a cover 160k, and a conductive film 180k, in place of the convex member 40, the cover 60j, and the conductive film 80j (see FIG. 9). In FIG. 10, the case 110k can be formed with any material such as plastic which can be resin-molded. This enables the convex member 140k, the cover 160k and the conductive film 180k to be constituted at low cost.

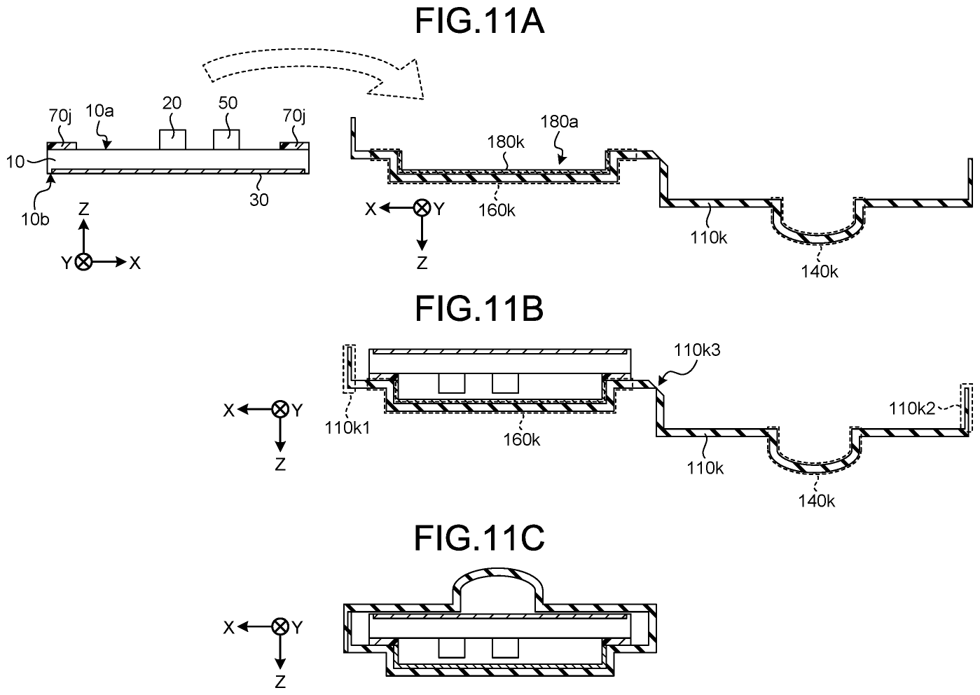

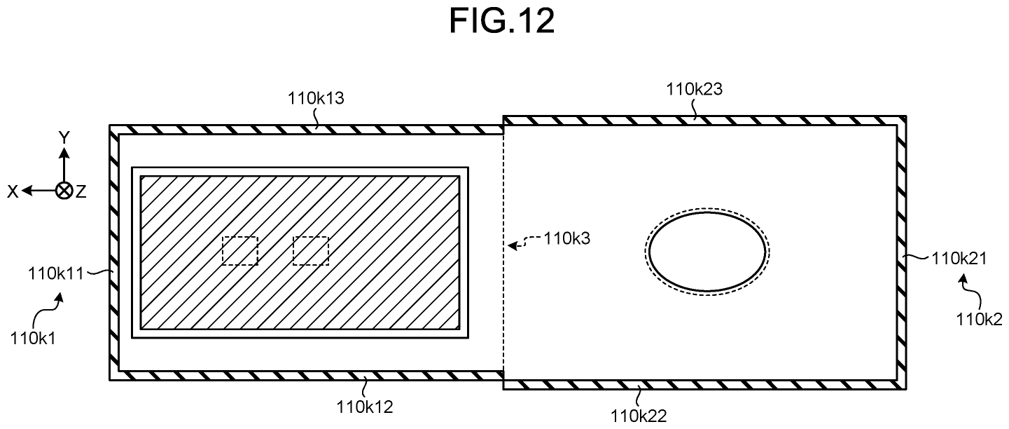

The vibration sensor 1k may be manufactured as illustrated in FIGS. 11A to 11C. FIGS. 11A to 11C are cross-sectional diagrams of process illustrating a manufacturing method of the vibration sensor 1k according to the fourth modified example of the embodiment.

In process illustrated in FIG. 11A, the piezoelectric element 20 and other elements 50 are mounted on the front surface 10a of the substrate 10 and an adhesive agent is applied to a circumferential portion of the substrate 10 to form the adhesive layer 70j. The conductive film 30 is formed on the back surface 10b of the substrate 10 through plating, or the like. The case 110k including the convex member 140k and the cover 160k is integrally molded by resin molding, or the like, and the conductive film 180k is formed on a surface corresponding to the inner surface of the cover 160k through plating, or the like.

In process illustrated in FIG. 11B and FIG. 12, the substrate 10 is provided upside down to put the piezoelectric element 20 and the other components 50 into an opening structure 180a of the cover 160k. Then, the adhesive layer 70j is brought into contact with the case 110k, and the substrate 10 and the case 110k are bonded to each other via the adhesive layer 70j.

Note that, in the case 110k, a fitting structure including an inner wall portion 110k1 and an outer wall portion 110k2 is provided. As illustrated in FIG. 11B, in an XZ cross-sectional view, the inner wall portion 110k1 rises in the −Z direction from a height of a plane on which the substrate 10 is bonded. As illustrated in FIG. 12, in an XY planar view, the inner wall portion 110k1 includes a portion 110k11 extending in the Y direction, a portion 110k12 extending in the −X direction from an end portion on the −Y side of the portion 110k11, and a portion 110k13 extending in the −X direction from an end portion on the +Y side of the portion 110k11.

As illustrated in FIG. 11B, in an XZ cross-sectional view, the outer wall portion 110k2 rises in the −Z direction from a height of the end portion on the −Z side of the convex member 140k. As illustrated in FIG. 12, in an XY planar view, the outer wall portion 110k2 includes a portion 110k21 extending in the Y direction, a portion 110k22 extending in the +X direction from an end portion on the −Y side of the portion 110k21, and a portion 110k23 extending in the +X direction from an end portion on the +Y side of the portion 110k21.

A width in the Y direction of an outer surface of the inner wall portion 110k1 corresponds to a width in the Y direction of an inner surface of the outer wall portion 110k2, so that the inner wall portion 110k1 and the outer wall portion 110k2 are fitted to each other.

In process illustrated in FIG. 11C, the case 110k is folded on a broken line 110k3 such that the inner wall portion 110k1 and the outer wall portion 110k2 are fitted to each other, and thereby the substrate 10 is stored inside the case 110k.

In this manner, in the fourth modified example of the embodiment, the convex member 140k, the cover 160k and the conductive film 180k can be manufactured through simple process.

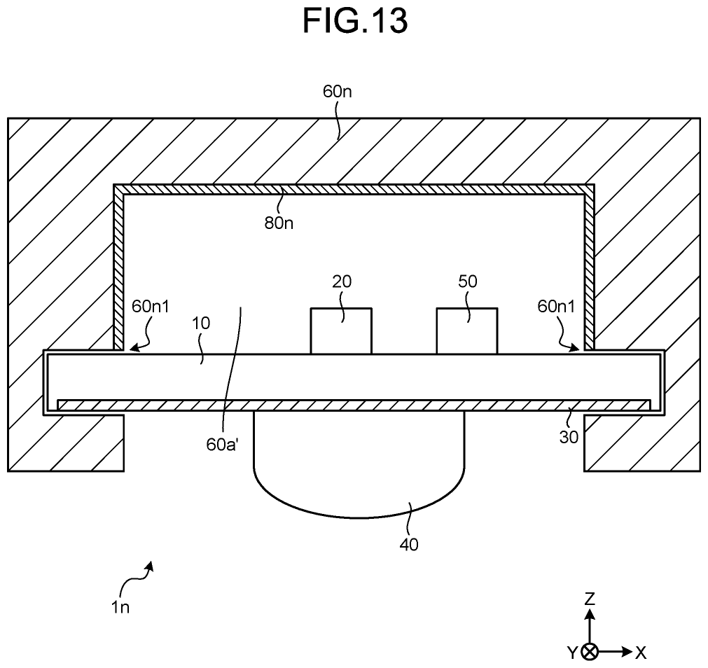

As illustrated in FIG. 13, a cover 60n of a vibration sensor 1n may be constituted to be in a fitted type. FIG. 13 is a cross-sectional diagram illustrating a configuration of the vibration sensor 1n according to a fifth modified example of the embodiment. The vibration sensor 1n includes the cover 60n and a conductive film 80n, in place of the cover 60j and the conductive film 80j (see FIG. 9), and does not need to include the adhesive layer 70j (see FIG. 9). The cover 60n is provided with, on an inner surface of an opening structure 60a′ of the cover 60n, grooves 60n1 into which a +X side end portion and a −X side end portion of the substrate 10 are to be respectively fitted. On the inner surface of the opening structure 60a′, the grooves 60n1 can be formed such that a portion closest to the −Z side of the convex member 40 is positioned on the −Z side of an end portion of the opening structure 60a′ of the cover 60n when the substrate 10 is fitted.

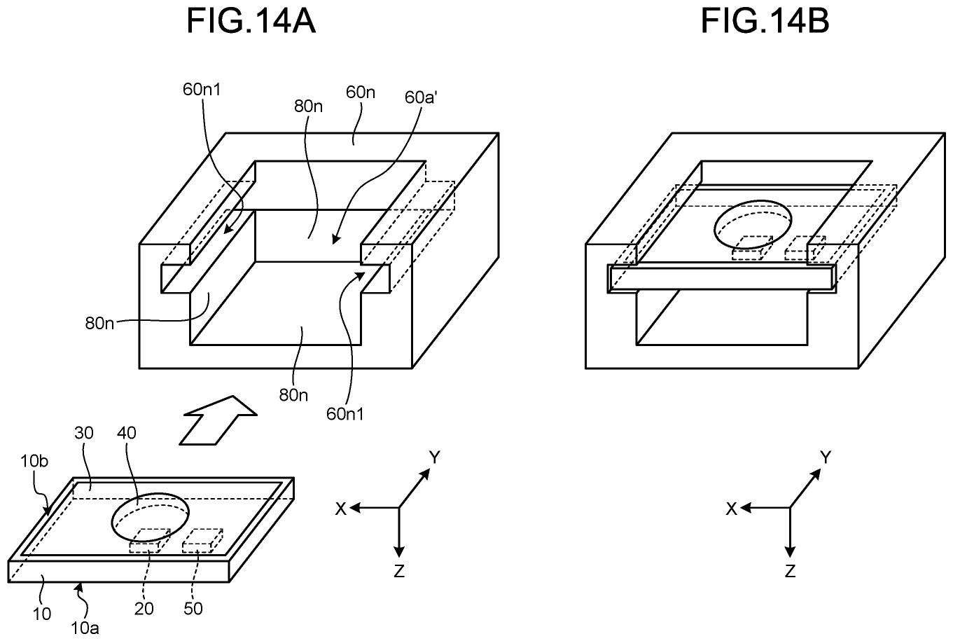

The vibration sensor 1n may be manufactured as illustrated in FIGS. 14A and 14B. FIGS. 14A and 14B are cross-sectional diagrams of process illustrating a manufacturing method of the vibration sensor 1n according to the fifth modified example of the embodiment.

In process illustrated in FIG. 14A, the piezoelectric element 20 and other elements 50 are mounted on the front surface 10a of the substrate 10. The conductive film 30 is formed on the back surface 10b of the substrate 10 by plating, or the like, and the convex member 40 is fixed on the conductive film 30. The conductive film 80n is formed by plating, or the like, in a region which is to be on a side of the piezoelectric element 20 on the inner surface of the cover 60n.

In process illustrated in FIG. 14B, the substrate 10 is fitted into the grooves 60n-1 of the cover 60n in a direction in which the piezoelectric element 20 and other components 50 are stored inside the opening structure 60a′ of the cover 60n, to complete storage of the substrate 10 inside the cover 60n.

In this manner, in the fifth modified example of the embodiment, the cover 60n and the conductive film 80n can be manufactured through further simple process.

According to the present invention, it is possible to provide a vibration sensor being suitable for improving detection accuracy of vibration.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A vibration sensor comprising:
a substrate including a first principal surface and a second principal surface opposite to the first principal surface, the substrate transmitting vibration;
a convex member fixed in a first fixing region on the first principal surface of the substrate, configured to receive external vibration and transmit the vibration to the substrate; and
a piezoelectric element disposed within a second fixing region on the second principal surface of the substrate so as to detect the vibration transmitted to the substrate, the second fixing region corresponding to, in a plan view, the first fixing region of the substrate on which the convex member is fixed.

2. The vibration sensor according to claim 1, wherein the second principal surface of the substrate has a non-fixing region at a periphery of the second fixing region.

3. The vibration sensor according to claim 2,
wherein the piezoelectric element includes a piezoelectric body and a pair of terminal electrodes that are respectively provided on respective ends of the piezoelectric body; and
wherein the vibration sensor further includes a first electrode and a second electrode, each provided on the substrate, one of the pair of terminal electrodes being electrically connected to the first electrode, the other of the pair of terminal electrodes being electrically connected to the second electrode.

4. The vibration sensor according to claim 3, wherein:
the one of the pair of terminal electrodes and the first electrode are electrically connected with a conductive bonding material, and
the other of the pair of terminal electrodes and the second electrode are electrically connected with a conductive bonding material.

5. The vibration sensor according to claim 2, wherein the convex member includes a flat surface to be fixed on the substrate.

6. The vibration sensor according to claim 5, wherein, when stress is applied to the convex member, the non-fixing region is curved more than the second fixing region.

7. The vibration sensor according to claim 3, further comprising an element that constitutes a circuit together with the piezoelectric element, the element being disposed on the second principal surface of the substrate in a region that avoids a boundary between the second fixing region and the non-fixing region.

8. A vibration sensor comprising:
a substrate including a first principal surface and a second principal surface opposite to the first principal surface, the substrate transmitting vibration;
a convex member fixed on the first principal surface of the substrate so as to receive external vibration and transmit the vibration to the substrate;
a piezoelectric element provided on the second principal surface of the substrate to detect the vibration transmitted to the substrate; and
an element disposed in a region on the second principal surface of the substrate that avoids a boundary between a first fixing region and a first non-fixing region on the substrate in a plan view, the first fixing region being a region on which the convex member is fixed to the first principal surface of the substrate, the first non-fixing region being a region at a periphery of the first fixing region.

9. The vibration sensor according to claim 8, wherein the element is electrically connected to a conductive pattern formed on the substrate, thereby constituting a circuit together with the piezoelectric element.

10. The vibration sensor according to claim 9, wherein:
the second principal surface of the substrate has a second fixing region corresponding to the first fixing region and a second non-fixing region at a periphery of the second fixing region, and
the piezoelectric element is disposed within the second fixing region.

11. The vibration sensor according to claim 10,
wherein the piezoelectric element includes an piezoelectric body and a pair of terminal electrodes respectively provided on respective ends of the piezoelectric body; and
wherein the vibration sensor further includes a first electrode and a second electrode, each being provided on the substrate, one of the pair of terminal electrodes being electrically connected to the first electrode, the other of the pair of terminal electrodes being electrically connected to the second electrode.

12. The vibration sensor according to claim 11, wherein:
the one of the pair of terminal electrodes and the first electrode are electrically connected with a conductive bonding material, and
the other of the pair of terminal electrodes and the second electrode are electrically connected with a conductive bonding material.

13. The vibration sensor according to claim 8, wherein the convex member includes a flat surface to be fixed on the substrate.

14. The vibration sensor according to claim 7, wherein a width in a planar view of the convex member is smaller than that of the substrate.

15. A vibration sensor comprising:
a substrate including a first principal surface and a second principal surface opposite to the first principal surface;
a piezoelectric element provided on the second principal surface of the substrate to detect vibration of the substrate;
a rod-like member whose one end is fixed on the first principal surface of the substrate; and
a convex member including a convex surface and a surface opposite thereto on which another end of the rod-like member is fixed, the convex member being configured to receive external vibration and transmit the vibration to the substrate via the rod-like member.

16. The vibration sensor according to claim 1, further comprising a cover provided on the second principal surface of the substrate to enclose the piezoelectric element.

17. The vibration sensor according to claim 16, wherein an inner surface of the cover is covered with a conductive film.

18. The vibration sensor according to claim 17, wherein the cover includes, on the inner surface, a groove enabling an end portion of the substrate to be fitted into.
